(19) United States
(12) Patent Application Publication
(10) Pub. No.: US 2007/0171735 A1
(43) Pub. Date: Jul. 26, 2007

(54) Latency circuit for semiconductor memories

(76) Inventor: Jong-Hoon Oh, Chapel Hill, NC (US)

Correspondence Address: DICKE, BILLIG & CZAJA, FIFTH STREET TOWERS, 100 SOUTH FIFTH STREET, SUITE 2200, MINNEAPOLIS, MN, 55402, US

(21) Appl. No.: 11/339,745

(22) Filed: Jan. 25, 2006

(51) Int. Cl. G11C 7/00

(52) U.S. Cl. 365/189.12

(57) ABSTRACT

A random access memory includes an array of memory cells, a mode register and a controller. The mode register is configured to hold a programmable minimum timing requirement. The controller is configured to retrieve the programmable minimum timing requirement and to access the array of memory cells in a double data rate prefetch mode in response to a read command after the programmable minimum timing requirement is met.

### BACKGROUND

There are many types of dynamic random access memory (DRAM) systems, including single data rate (SDR) synchronous DRAM (SDRAM), double data rate (DDR) synchronous DRAM (SDRAM), and others. In DDR SDRAM, the read and write operations are synchronized to a system clock supplied by a host system that includes the DDR SDRAM. Operations in DDR SDRAM are performed on both the rising and falling edges of the system clock (in SDR, operations are only performed on a rising edge). DDR SDRAM uses a double data rate architecture to achieve high speed operation. The double data rate architecture is essentially a 2n prefetch architecture with an interface designed to transfer two data words per clock cycle at the DQs. A single read or write access for the DDR SDRAM effectively consists of a single 2n bit wide, one clock cycle data transfer at the internal memory array and two corresponding n bit wide, one half clock cycle data transfers at the DQs.

Read and write accesses to DDR SDRAM are burst oriented. Accesses start at a selected location and continue for a programmed number of locations in a programmed sequence. Accesses begin with the registration of an activate command, which is followed by a read or write command. The address bits registered coincident with the activate command are used to select the bank and row to be accessed. The address bits registered coincident with the read or write command are used to select the bank and the starting column location for the burst access.

A Row Address Strobe (RAS) signal is used to latch in the row addresses for selected memory cells and initiate a row access during a read or write operation and a Column Address Strobe (CAS) signal is used to latch in the column addresses for selected memory cells and initiate a column access during a read or write operation. CAS latency is the time between the initialization of a read command and the data being available on the output pads or pins of a memory. CAS latency is specified in clock cycles. The delay between an activate command and the first read command is referred to as the RAS to CAS delay, and this timing requirement is called tRCD.

Some types of DRAM devices, such as DDR SDRAM, typically have a minimum CAS latency of two or more clock cycles. Others, such as DDR2 SDRAM, can double the CAS latency and clock cycles. In any event, tRCD in DDR SDRAM cannot be shorter than a minimum time, or the memory circuit may fail. As such, additive latency (AL) is introduced to a read command, and added to tRCD in order to make the command assertion more flexible. Introduction of AL in some instances, however, becomes overhead to read or write latency if a read or write command is asserted after tRCD is satisfied.

For these and other reasons, there is a need for the present invention.

### SUMMARY

One embodiment of the present invention provides a random access memory. The random access memory includes an array of memory cells, a mode register and a controller. The mode register is configured to hold a programmable minimum timing requirement. The controller is configured to retrieve the programmable minimum timing requirement and to access the array of memory cells in a double data rate prefetch mode in response to a read command after the programmable minimum timing requirement is met.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a block diagram illustrating a random access memory according to one embodiment of the present invention.

FIG. 2 is a timing diagram illustrating one embodiment of timing of signals for a circuit for a random access memory.

FIGS. 3A and 3B illustrate tables for configuring a programmable signal according to one embodiment of the invention.

FIG. 4 is a block diagram illustrating of a circuit for generating a programmable signal according to one embodiment of the invention.

FIG. 5 is a timing diagram illustrating timing of signals for a circuit for a random access memory according to one embodiment of the invention.

FIG. 6 is a timing diagram illustrating timing of signals for a circuit for a random access memory according to another embodiment of the invention.

FIG. 7 are block diagrams illustrating circuits for generating a programmable signal according to one embodiment of the invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

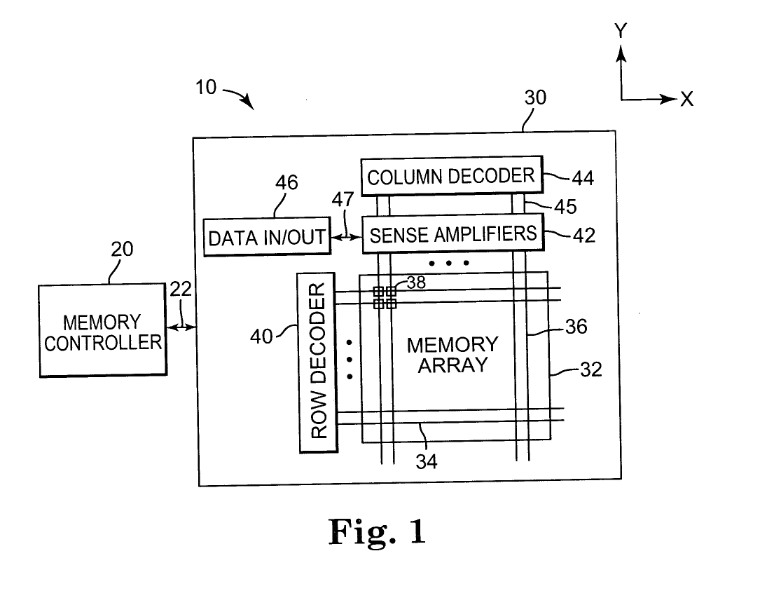

FIG. 1 is a block diagram illustrating a random access memory 10. In one embodiment, random access memory 10 is a double data rate synchronous dynamic random access memory (DDR SDRAM). Memory 10 includes a memory controller 20 and at least one memory bank 30. Memory bank 30 includes an array of memory cells 32, a row decoder 40, a column decoder 44, sense amplifiers 42, and data in/out circuit 46. Memory controller 20 is electrically coupled to memory bank 30, indicated at 22.

Conductive word lines 34, referred to as row select lines, extend in the x-direction across the array of memory cells 32. Conductive bit lines 36, referred to as column select lines, extend in the y-direction across the array of memory cells 32. A memory cell 38 is located at each cross point of a word line 34 and a bit line 36. Each word line 34 is electrically coupled to row decoder 40 and each bit line 36 is electrically coupled to a sense amplifier 42. The sense amplifiers 42 are electrically coupled to column decoder 44 through conductive column decoder lines 45 and to data in/out circuit 46 through data lines 47.

Data in/out circuit 46 includes a plurality of latches and data input/output (I/O) pads or pins (DQs) to transfer data between memory bank 30 and an external device. In one embodiment, there is one data in/out circuit 46 for all memory banks. In another embodiment, there is one data in/out circuit 46 for every memory bank or groups of memory banks. Data written into memory bank 30 is presented as voltages on the DQs from an external device. The voltages are translated into the appropriate logic levels and stored in selected memory cells 38. Data read from memory bank 30 is presented by memory bank 30 on the DQs for an external device to retrieve. Data read from selected memory cells 38 appears at the DQs once access is complete and the output is enabled. At other times, the DQs are in a high impedance state.

Data in/out circuit 46 includes a first in/first out (FIFO) memory block and a bypass around the FIFO memory block. The bypass is electrically coupled between the data lines 47 and each DQ. During a read operation, data passes through the FIFO memory block for a column address strobe (CAS) latency greater than one and through the bypass around the FIFO memory block for a CAS latency of one.

Memory controller 20 controls reading data from and writing data to memory bank 30. During a read operation, memory controller 20 passes the row address of a selected memory cell or cells 38 to row decoder 40. Row decoder 40 activates the selected word line 34. As the selected word line 34 is activated, the value stored in each memory cell 38 coupled to the selected word line 34 is passed to the respective bit line 36. The value of each memory cell 38 is read by a sense amplifier 42 electrically coupled to the respective bit line 36. Memory controller 20 passes a column address of the selected memory cell or cells 38 to column decoder 44. Column decoder 44 selects which sense amplifiers 42 pass data to data in/out circuit 46 for retrieval by an external device.

During a write operation, the data to be stored in array 32 is placed in data in/out circuit 46 by an external device. Memory controller 20 passes the row address for the selected memory cell or cells 38 where the data is to be stored to row decoder 40. Row decoder 40 activates the selected word line 34. Memory controller 20 passes the column address for the selected memory cell or cells 38 where the data is to be stored to column decoder 44. Column decoder 44 selects which sense amplifiers 42 are passed the data from data in/out circuit 46. Sense amplifiers 42 write the data to the selected memory cell or cells 38 through bit lines 36.

In DDR SDRAM, the read and write operations are synchronized to a system clock. The system clock is supplied by a host system that includes the memory 10. DDR SDRAM operates from a differential clock, CK and bCK. The crossing of CK going high and bCK going low is referred to as the positive edge of CK. Commands such as read and write operations, including address and control signals, are registered at the positive edge of CK. Operations are performed on both the rising and falling edges of the system clock.

The DDR SDRAM uses a double data rate architecture to achieve high speed operation. The double data rate architecture is essentially a 2n prefetch architecture with an interface designed to transfer two data words per clock cycle at the DQs. A single read or write access for the DDR SDRAM effectively consists of a single 2n bit wide, one clock cycle data transfer at the internal memory array and two corresponding n bit wide, one half clock cycle data transfers at the DQs.

A bidirectional data strobe (DQS) is transmitted along with data for use in data capture at data in/out circuit 46. DQS is a strobe transmitted by the DDR SDRAM during read operations and by the memory controller, such as memory controller 20, during write operations. DQS is edge aligned with data for read operations and center aligned with data for write operations. Input and output data is registered on both edges of DQS.

Read and write accesses to the DDR SDRAM are burst oriented. Accesses start at a selected location and continue for a programmed number of locations in a programmed sequence. Accesses begin with the registration of an active command, which is followed by a read or write command. The address bits registered coincident with the active command are used to select the bank and row to be accessed. The address bits registered coincident with the read or write command are used to select the bank and the starting column location for the burst access.

A DDR-II SDRAM has the same features as a DDR SDRAM, except that the data rate is doubled. The DDR-II SDRAM architecture is essentially a 4n prefetch architecture with an interface designed to transfer four data words per clock cycle at the DQs. A single read or write access for the DDR-II SDRAM effectively consists of a single 4n bit wide, one clock cycle data transfer at the internal memory array and four corresponding n bit wide, one quarter clock cycle data transfers at the DQs. In one embodiment, memory 10 is a DDR-II SDRAM.

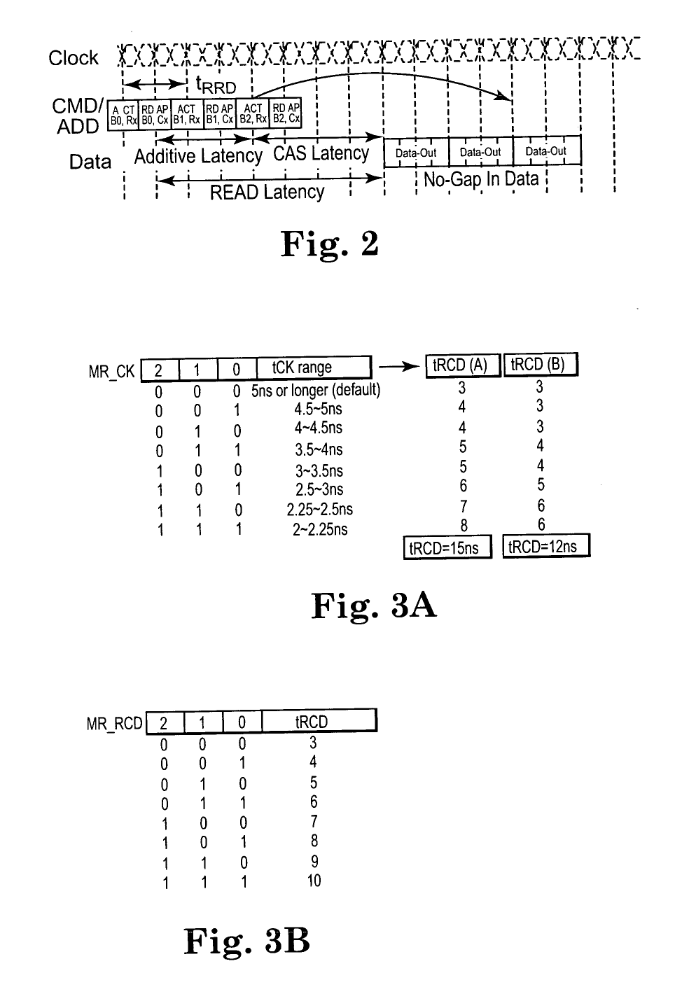

FIG. 2 is a timing diagram illustrating timing of signals for a circuit for a random access memory such as memory 10. The number of clock cycles between the issuing of an activate command (ACT) and the first read command (RD) is referred to as the RAS to CAS Delay tRCD. The tRCD must be satisfied before the next active command is issued or the memory circuit may fail. Because DDR-II SDRAM architecture doubles the data rate relative to DDR SDRAM to a 4n prefetch architecture, additive latency (AL) is introduced to a read command, and thus added to tRCD, in order to make the command assertion more flexible.

In a DDR-II SDRAM architecture without AL, activate commands (ACT) and read commands (RD) will be separated in some instances by dead clock cycles in order to assure that tRCD is met. This can lead to gaps in data output. With AL, however, subsequent read commands can be suspended internally by the period of the AL. In this way, memory controller 20 has more freedom in issuing active commands.

Although AL improves the flexibility and efficiency of memory controller 20, the introduction of AL in some instances, however, becomes overhead to read or write latency if a read or write command is asserted after tRCD is satisfied. In other words, if tRCD is already satisfied, adding AL after each subsequent read command becomes unnecessary penalty or delay to the system.

In this way, one embodiment of the present invention provides a variable or programmable tRCD that allows memory 10 to eliminate AL, but at that same time also prevent system errors that can arise from back-to-back active commands. In one embodiment, tRCD is applied at each active command for a variable number of clock cycles dependant on the clock frequency. In this way, no AL is needed on each subsequent read or write command after tRCD is satisfied. This reduces overhead while still providing increased flexibility and efficiency of memory 10.

In one embodiment, the variable tRCD is calculated as the number of clock cycles between memory controller 20 and memory bank 30. In one case, a programmable mode register (MR_CK) is provided within memory 10. In this way, memory controller 20 programs the clock cycle time of the operation into mode register MR_CK and based on this, the memory can read out a corresponding number of clock cycles for tRCD from the mode register (MR_CK).

FIG. 3A illustrates a table for configuring a programmable mode register (MR_CK) with a clock frequency signal according to one embodiment of the invention. According to the frequency range of the system clock signal used in memory 10, a particular number of clock cycles are used in order to achieve a tRCD of either 15 or 12 ns according to one embodiment. As illustrated, for a clock frequency of 5 ns or less, 3 cycles are used for tRCD in either a 15 ns or a 12 ns embodiment; for 4-5 ns clock frequency, 4 cycles are used for tRCD in a 15 ns embodiment and 3 cycles are used for tRCD in a 12 ns embodiment; for 3-4 ns clock frequency, 5 cycles are used for tRCD in a 15 ns embodiment and 4 cycles are used for tRCD in a 12 ns embodiment; for 2.5-3 ns clock frequency, 6 cycles are used for tRCD in a 15 ns embodiment and 5 cycles are used for tRCD in a 12 ns embodiment; for 2.25-2.5 ns clock frequency, 7 cycles are used for tRCD in a 15 ns embodiment and 6 cycles are used for tRCD in a 12 ns embodiment; and for 2-2.25 ns clock frequency, 8 cycles are used for tRCD in a 15 ns embodiment and 6 cycles are used for tRCD in a 12 ns embodiment.

As such, once programmable mode register (MR_CK) is set with the appropriate value according to the system requirements, controller 20 no longer uses AL. Instead, each time an active command (ACT) is sent, the tRCD value associated with the programmable mode register (MR_CK) is issued. Any read/write commands that are received during the tRCD cycles are then suspended until the tRCD is complete. In this way, controller 20 has the flexibility of allowing back-to-back commands without causing undue overhead by using AL with each read command.

In another embodiment, the variable tRCD is directly programmed into a mode register (MR_RCD) as a number of cycles. FIG. 3B illustrates a table for configuring a programmable mode register (MR_RCD) that holds values for tRCD, as a number of cycles, that are based on the clock frequency and system characteristics. Once programmed into mode register (MR_RCD) of the memory, controller 20 can then simply extract the number of cycles to be used for tRCD. Again with this embodiment, once programmable mode register (MR_RCD) is set with the appropriate number of cycles according to the system requirements, controller 20 no longer uses AL. Instead, each time an active command (ACT) is sent, the tRCD value associated with the programmable mode register (MR_RCD) is issued. Any read/write commands that are received during the tRCD cycles are then suspended until the tRCD is complete. In this way, controller 20 has the flexibility of allowing back-to-back commands without causing undue overhead by using AL with each read command.

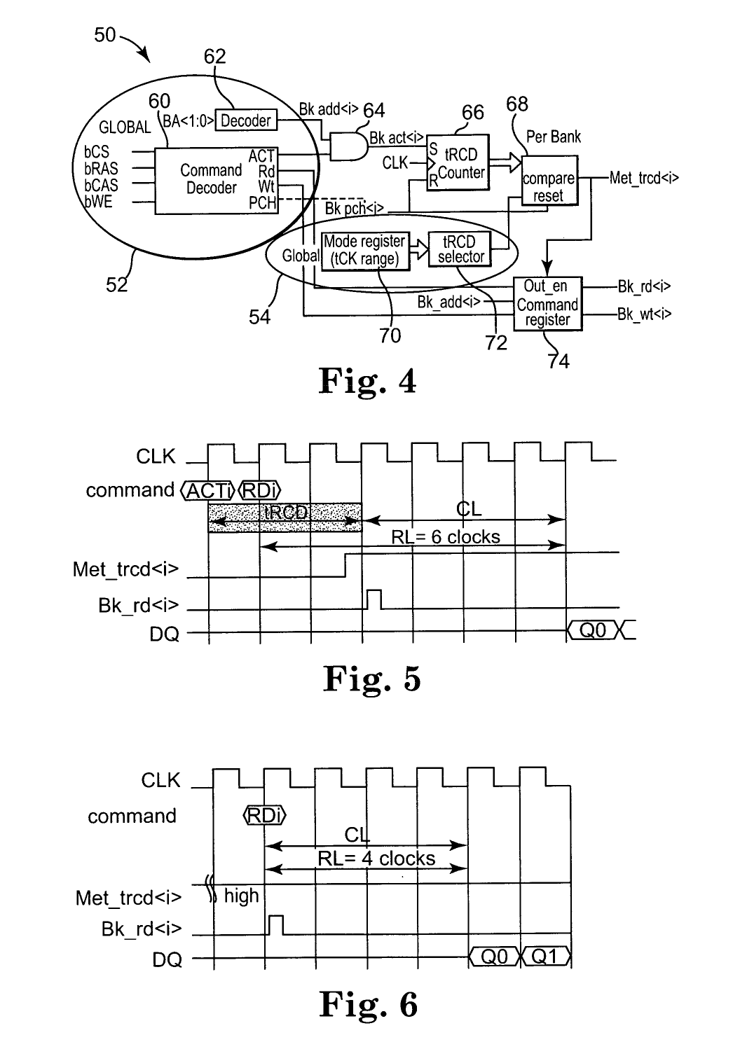

One embodiment of a signal generating circuit 50 is illustrated in FIG. 4. Signal generating circuit 50 can be used in memory 10 to use the variable tRCD thereby allowing memory 10 to eliminate AL, but at that same time also prevent system errors that can arise from read command following an active command before tRCD is met. One embodiment of signal generating circuit 50 includes command decoder 60, decoder 62, AND logic gate 64, tRCD counter 66, compare logic 68, mode register 70, tRCD selector 72 and command register 74. In one case, first and second sections 52 and 54 of circuit 50 are provided on a global basis to memory 10, and the remaining portions of circuit 10 are provided to each memory bank 30.

In operation, command decoder 60 receives the command signals from controller 20, such as bCS (bank column select), bRAS (bank row address strobe), bCAS(bank column address strobe), and bWE (bank write enable). Decoder 62 receives the bank active signal (BA). When the bank active (BA) is triggered and ACT is high (from command decoder 60), and a bank is selected (at decoder 62), then the BK_ADD<i> signal from AND logic gate 64 is high. The BK_ADD<i> signal is received by and sets tRCD counter 66. As such, tRCD counter 66 starts to count by the number of clock cycles (CLK).

Then, at compare logic 68, the output of tRCD counter 66 is then compared against the tRCD signal from tRCD selector 72, which is in one embodiment selected from the clock signal stored in mode register 70 (as described above with reference to FIG. 3A). In another embodiment tRCD can be pulled directly from mode register 70 (as described above with reference to FIG. 3B) for comparison at compare logic 68 against the output of tRCD counter 66.

The output from compare logic 68 is thus a signal indicating that tRCD has been met (Met_tRCD<i> signal). The Met_tRCD<i> signal will transition high when the number of clock cycles stored for the tRCD signal in mode register 70 is met by tRCD counter 66. The Met_tRCD<i> signal is then supplied to command register 74 to trigger bank read (Bk_rd<i>) and bank write (Bk_wt<i>) signals. When the Met_tRCD<i> signal is low, indicating that tRCD is still not met, command register 74 continues to suspend Bk_rd<i> and Bk_wt<i> signals.

FIG. 5 is a timing diagram illustrating timing of signals for signal generating circuit 50 configured within memory 10 in accordance with one embodiment of the present invention. The system clock (CLK) is illustrated across the top if the figure. An active command (ACTi) and read command (RDi) are illustrated on the command bus and are issued back-to-back in the example. In a typical DDR-II SDRAM, AL would need to be used in order to prevent an error due to the issuance of these back-to-back commands. With signal generating circuit 50, however, the tRCD signal from stored in a mode register is used to internally suspend the read command (RDi) until tRCD is satisfied, thereby avoiding any error on the command bus.

As illustrated in FIG. 5, the Met_tRCD<i> signal remains low until the number of clock cycles stored for tRCD is satisfied. In the example, this is for three clock cycles. Once tRCD is satisfied, the Bk_rd<i> signal transitions high thereby removing the suspension of the read command (RDi). Data will then begin its bust onto the data bus after the CAS latency, which is four clock cycles in the example. Since the number of clock cycles stored for tRCD in the mode register is tailored to the system clock and characteristics, suspension of the read command (RDi) for the period that the Bk_rd<i> signal is held low prevents errors on the command bus and also obviates the need for an AL signal.

FIG. 6 also illustrates a timing diagram illustrating timing of signals for signal generating circuit 50 configured within memory 10 in accordance with one embodiment of the present invention. In this diagram, a read command (RDi) is asserted after tRCD has already been met. As such, the Met_tRCD<i> signal remains high since tRCD is already met, and thus, the Bk_rd<i> signal goes high as soon as the read command (RDi) is asserted. Since no AL signal is asserted with each read signal within memory 10 in accordance with one embodiment of the present invention (as would be the case with current DDR-II systems), CAS latency also begins immediately as the read command (RDi) is asserted. In this way, data begins its bust onto the data bus after the CAS latency, which is four clock cycles in the example.

In the examples of the embodiments of the invention illustrated in FIGS. 5 and 6, the removal of AL is illustrated by the reduction in read latency (RL). In FIG. 5, where an active command (ACTi) is immediately followed by a read command (RDi), the RL is the sum of the remaining tRCD when the read command (RDi) is asserted (two cycles in the illustration) and the CL (four cycles in the illustration). In FIG. 6, where a read command (RDi) is asserted after tRCD is already satisfied, the RL is equal to the CL (four cycles in the illustration).

By contrast, in FIG. 2, where an active command (ACT_B0,Rx) is immediately followed by a read command (RD AP_B0,Cx), the RL is the sum of the AL (three cycles in the illustration) and the CL (four cycles in the illustration). As such, the use of AL with each read command adds to the overhead of the memory and thereby decreases bandwidth of the memory system.

In one embodiment of the present invention, controller 20 tracks or counts RL when a read command is issued before tRCD is met. As such, the total RL in that case will be the number of clock cycles remaining until tRCD is met plus the number of clock cycles in CL. Otherwise, RL is equal to CL in those cases where tRCD is already met.

In accordance with one embodiment of the present invention, read or write commands can be issued before the tRCD requirement is met without causing error. Within memory bank 30, a circuit, such as signal generating circuit 50, the invention uses a counter circuit to issue read or write command as soon as tRCD requirement to the specific bank is met. This effectively places part of command queue inside memory bank 30. In this way, controller 20 is freed from the limitation of tracking whether tRCD has been met for any particular bank. This increases the efficiency of controller 20 and improves the bus utilization without any access penalty, such as AL.

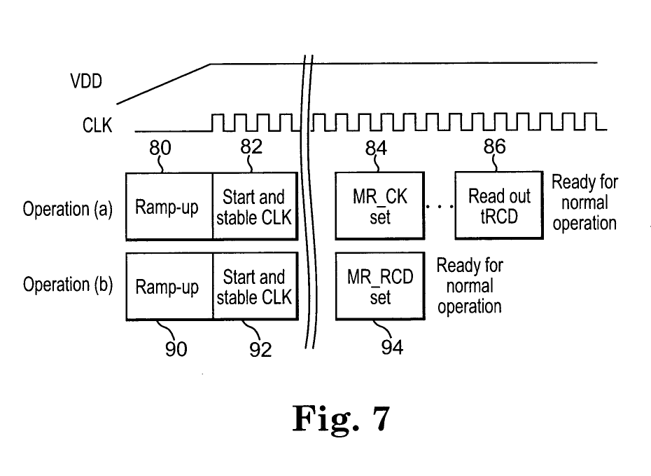

FIG. 7 illustrates examples for programming tRCD, for example into a mode register, as a number of clock cycles. Two operations are illustrated: operation (a) corresponds to the example given in FIG. 3A discussed above and operation (b) corresponds to the example given in FIG. 3B discussed above. In each of cases (a) and (b), operation begins with a ramp up at 80/90 and then start and stable clock (CLK) at 82/92.

In the case of operation (a), once the CLK is stabilized its frequency is stored in the mode register (MR_CK) at 84, as described above with reference to FIG. 3A. Based on the value set at 84, tRCD is then read at 86 to be used in conjunction with signal generating circuit 50 in accordance with one embodiment of the present invention. Once mode register is set at 84, tRCD does not need to be reset as long as CLK continues to be stable and unchanged.

In the case of operation (b) once the CLK is stabilized tRCD is stored in the mode register (MR_tRCD) at 94, as described above with reference to FIG. 3B. As such, tRCD is then ready to be read out and used in conjunction with signal generating circuit 50 in accordance with one embodiment of the present invention. Once mode register is set at 94, tRCD does not need to be reset as long as CLK continues to be stable and unchanged.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A random access memory comprising:
an array of memory cells;
a mode register configured to hold a programmable minimum timing requirement; and
a controller configured to retrieve the programmable minimum timing requirement and to access the array of memory cells in a double data rate prefetch mode in response to a read command after the programmable minimum timing requirement is met.

2. The random access memory of claim 1, wherein the programmable minimum timing requirement is a minimum time between a row address strobe and a column address strobe.

3. The random access memory of claim 2, wherein the minimum time between a row address strobe and a column address strobe is calculated as a number of clock cycles and stored into the mode register.

4. The random access memory of claim 3, wherein the controller is configured to determine the number of clock cycles based upon the frequency of a system clock and characteristics of the random access memory

5. A random access memory comprising:
an array of memory cells;
a signal generating circuit within the random access memory for generating a programmable minimum timing signal; and
a controller configured to be responsive to the retrieve the programmable minimum timing signal and to access the array of memory cells in a double data rate prefetch mode in response to a read command after the programmable minimum timing signal transitions states indicating that a minimum time parameter has been met.

6. The random access memory of claim 5, wherein the signal generating circuit further comprises a counter configured to track clock cycles after a row address strobe and output a signal indicative of number of clock cycles.

7. The random access memory of claim 6, wherein the signal generating circuit further comprises a mode register configured to store a minimum time between a row address strobe and a column address strobe and a column address strobe and generate an output signal indicative of the minimum time.

8. The random access memory of claim 7, wherein the signal generating circuit further comprises a comparator configured to compare the output of the counter with the output of the mode register in order to generate a signal indicative of when the minimum time has been met.

9. The random access memory of claim 8, wherein the minimum time stored in the mode register is a tRCD signal.

10. A random access memory comprising:
an array of memory cells;
means within the random access memory for storing a programmable time component representative of a number of clock cycles between a row address strobe and a column address strobe; and
a controller configured to retrieve the programmable time component and to access the array of memory cells in a double data rate prefetch mode in response to a read command after the programmable time component is met.

11. The random access memory of claim 10, wherein the programmable time component is stored outside the controller so that the controller does not have to calculate or store the programmable minimum timing requirement.

12. The random access memory of claim 10, wherein the programmable time component allows the controller to issue back-to-back read commands without using additive latency and without causing gaps in data read out of the memory cells.

13. A method of accessing a random access memory comprising:
storing a timing parameter representative of a minimum time required between a row address strobe and a column address strobe for the random access memory;
receiving an active command;
initiating counting in accordance with the timing parameter; and
accessing the array of memory cells in a double data rate prefetch mode in response to a read command after the counting in accordance with the timing parameter indicates that the minimum time required between a row address strobe and a column address strobe for the random access memory is met.

14. The method of claim 13, further including calculating the minimum time between a row address strobe and a column address strobe as a number of clock cycles and storing the number of clock cycles into a mode register.

15. The method of claim 14, further including determining the number of clock cycles based upon the frequency of a system clock and characteristics of the random access memory

16. A method for accessing a memory, the method comprising:
generating a programmable minimum timing signal; and
accessing an array of memory cells within the memory in a double data rate prefetch mode in response to a read command after the programmable minimum timing signal transitions states thereby indicating that a minimum time parameter has been met.

17. The method of claim 16, further including using tracking clock cycles after a row address strobe and outputting a signal indicative of number of clock cycles.

18. The method of claim 17, further including storing a minimum time between a row address strobe and a column address strobe and a column address strobe and generating an output signal indicative of the minimum time.

19. The random access memory of claim 18, further including comparing the signal indicative of number of clock cycles with the signal indicative of the minimum time in order to generate a signal indicative of when the minimum time has been met.

20. The random access memory of claim 19, wherein the minimum time stored is a tRCD signal.
